(19) United States
(12) Patent Application Publication
(10) Pub. No.: US 2022/0158665 A1
(43) Pub. Date: May 19, 2022

(54) CONTROL DEVICE

(71) Applicant: InterDigital CE Patent Holdings, Paris (FR)

(72) Inventor: Aaron BOUILLET, Noblesville, IN (US)

(21) Appl. No.: 17/598,375

(22) PCT Filed: Mar. 19, 2020
(86) PCT No.: PCT/IB2020/000319

§ 371 Date: Sep. 27, 2021

Related U.S. Application Data
(60) Provisional application No. 62/826,200, filed on Mar. 29, 2019.

(51) Int. Cl. H04B 1/00; H03F 3/24

(52) U.S. Cl. CPC H04B 1/0067; H03K 19/20; H03F 2200/451; H03F 3/24

(57) ABSTRACT

A circuit for controlling wireless transmissions. The circuit includes a multi-input logic gate coupled to a power amplifier for wireless transmission. A first input of the logic gate is coupled to a first wireless transceiver; and a second input of the gate is coupled to one or more wireless devices.

### TECHNICAL FIELD

The present embodiments generally relate to a control circuit in a wireless system. At least one embodiment relates to a control device for inhibiting wireless transmission.

### BACKGROUND

As wireless systems become more sophisticated, they need to accommodate an increasing number of wireless type applications and conflict between such applications. For example, Internet of Things (IoT) radios including Bluetooth, Zigbee, Thread, and the like operate in the same band as 802.11 WiFi. When operating within the same device, a strong WiFi transmission power can block a low-power incoming IoT signal. There are various ad-hoc mechanisms in practice driven through software to reserve time for IoT transmission or truncate WiFi transmission, if time of IoT transmission is known. However, such mechanisms incur a large overhead of software effort to implement and suffer from latency issues that degrade performance. The present embodiments have been devised with the foregoing in mind.

### SUMMARY

According to a first aspect, a circuit is provided. The circuit comprises a multi-input logic gate coupled to a power amplifier for wireless transmission wherein a first input of the logic gate is coupled to a first wireless transceiver; and a second input of the gate is coupled to one or more wireless devices.

According to a second aspect a device for wireless communications is provided. The device comprises a circuit including a multi-input logic gate coupled to a power amplifier for wireless transmission wherein a first input of the logic gate is coupled to a first wireless transceiver; and a second input of the gate is coupled to one or more wireless devices.

According to a third aspect a circuit is provided. The circuit comprises a controllable switch coupled to a power amplifier for wireless transmission wherein the switch is controllable by a wireless transceiver to terminate an input signal to the power amplifier.

### BRIEF DESCRIPTION OF THE DRAWINGS

FIG. 1 is a schematic diagram of a control circuit according to a first embodiment;

FIG. 2 is a schematic diagram of a control circuit according to a second embodiment; embodiment; and

FIG. 3 is a block diagram of an electronic wireless device work according to an embodiment.

### DETAILED DESCRIPTION

In a general embodiment an apparatus for controlling wireless transmission comprises a hardware control based on the output of one or more IoT radio devices. The control can trigger a hardware blocking or inhibiting of wireless transmission such as WiFi transmission by asserting a control signal via a control line

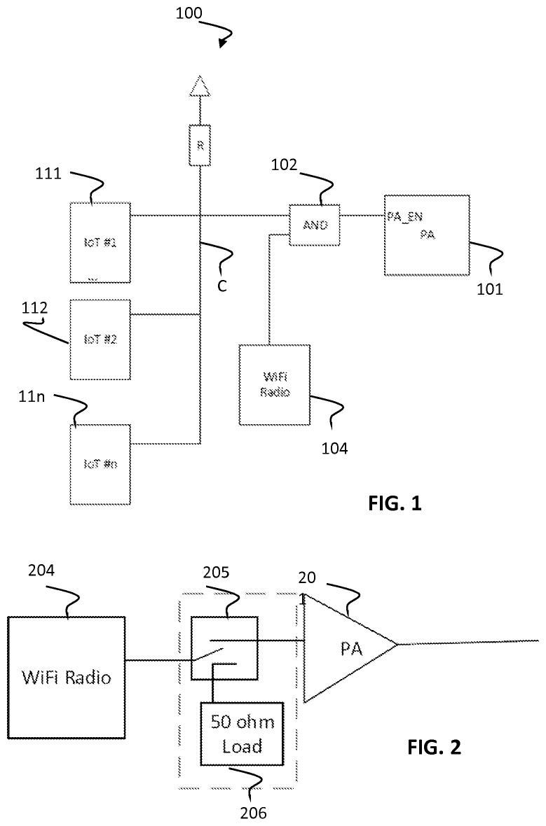

FIG. 1 illustrates a circuit for controlling wireless transmission in accordance with an embodiment. The circuit 100 comprises a power amplifier 101, a two input AND gate 102 coupled to an enable input PA_EN of the power amplifier 101. A first input of the AND gate is connected to the power enable control of a wireless transceiver 104, and a second input of the AND gate is coupled to the output of a number n of IoT devices 111, 112, . . . 11n by resistor circuity R and control line C. The wireless transceiver 104 may be a wifi transceiver operating in accordance with 802.11 WiFi. The Internet of Things (IoT) radios may include one or more of Bluetooth, Zigbee, Thread, and the like

The configuration of the AND gate and the control line C from the the IoT radios enables the power amplifier to be controlled to turn off by means of the enable input of the power amplifier 10. This enables an ongoing transmission to be truncated or future wifi transmissions to be inhibited or prevented until the line is released. In one or more embodiments the control line C may be a wired-OR type coupled to the outputs of the IoT radio devices to enable one or more of the IoT radio devices to assert the same control line C to control the wifi transmissions. WiFi packets lost due to this control mechanism can be retransmitted using normal WiFi protocols.

It may be the case that the power amplifier 101 is not operable to handle the case of its enable being low while power is present on the transmit input and thus may be damaged in this control mode. A separate control line may be added to the power amplifier 101 to enable the input to be safely terminated to a 50 ohm load as illustrated in FIG. 2. The embodiment of FIG. 2 comprises the output of a wireless transceiver 204 coupled to a switch 205 terminated by a 50 ohm load 206 at an input to the power amplifier. In some embodiments the switch 205 and load 206 of FIG. 2 may be connected between the output of the AND gate 102 of FIG. 1 and the input to the power amplifier 101.

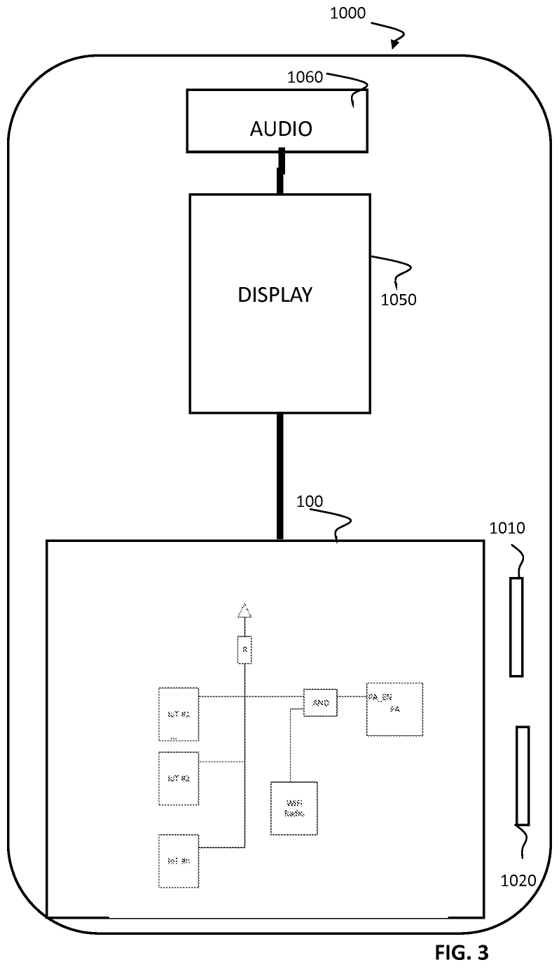

FIG. 3 illustrates a block diagram of an example of an electronic device in which embodiments may be implemented. Device 1000 comprises a control circuit 100 as illustrated in FIG. 1 including a wireless transceiver 104 for wife communications and a number of IoT radio devices operating according to one or more of Bluetooth, Zigbee, Thread, and the like.

The device 1000 may include the various components previous and is configured to perform one or more of the embodiments described in this disclosure. Examples of such devices include, but are not limited to, network devices such as gateways or a mobile device such as a tablet or a smart phone. Elements of device 1000, singly or in combination, may be embodied in a single integrated circuit, multiple ICs, and/or discrete components. In various embodiments, the system 1000 is communicatively coupled to other systems, or to other electronic devices, via, for example, a communications bus or through dedicated input and/or output ports.

The input to the elements of device 1000 may be provided through various input elements. Such input elements include, but are not limited to, (i) a wireless interface for receiving a wireless signal, (ii) a composite input terminal, (iii) a USB input terminal, and/or (iv) an HDMI input terminal.

In various embodiments, the input devices of block 1000 have associated respective input processing elements as known in the art. For example, the RF portion may be associated with elements suitable for (i) selecting a desired frequency (also referred to as selecting a signal, or band-limiting a signal to a band of frequencies), (ii) down converting the selected signal, (iii) band-limiting again to a narrower band of frequencies to select (for example) a signal frequency band which may be referred to as a channel in certain embodiments, (iv) demodulating the down converted and band-limited signal, (v) performing error correction, and (vi) demultiplexing to select the desired stream of data packets. The RF portion of various embodiments includes one or more elements to perform these functions, for example, frequency selectors, signal selectors, band-limiters, channel selectors, filters, downconverters, demodulators, error correctors, and demultiplexers. The RF portion may include a tuner that performs various of these functions, including, for example, down converting the received signal to a lower frequency (for example, an intermediate frequency or a near-baseband frequency) or to baseband. In one set-top box embodiment, the RF portion and its associated input processing element receives an RF signal transmitted over a wired (for example, cable) medium, and performs frequency selection by filtering, down converting, and filtering again to a desired frequency band. Various embodiments rearrange the order of the above-described (and other) elements, remove some of these elements, and/or add other elements performing similar or different functions. Adding elements may include inserting elements in between existing elements, for example, inserting amplifiers and an analog-to-digital converter. In various embodiments, the RF portion includes an antenna.

Additionally, the USB and/or HDMI terminals may include respective interface processors for connecting device 1000 to other electronic devices across USB and/or HDMI connections. It is to be understood that various aspects of input processing, for example, Reed-Solomon error correction, may be implemented, for example, within a separate input processing IC or within a processor included in device 1000. Similarly, aspects of USB or HDMI interface processing may be implemented within separate interface ICs or within processor 1710 as necessary.

Various elements of device 1000 may be provided within an integrated housing, Within the integrated housing, the various elements may be interconnected and transmit data therebetween using suitable connection arrangement for example, an internal bus as known in the art, including the I2C bus, wiring, and printed circuit boards.

The device 1000 may include a communication interface, that enables communication with other devices. The communication interface may include, but is not limited to, a transceiver configured to transmit and to receive data over a communication channel. The communication interface may include, but is not limited to, a modem or network card and the communication channel, may be implemented, for example, within a wired and/or a wireless medium.

Data may be streamed to the device 1000 in various embodiments, using a Wi-Fi network such as IEEE 802.11. The Wi-Fi signal of these embodiments is received over the communications channel and the communications interface which are adapted for Wi-Fi communications. The communications channel of these embodiments may be connected to an access point or router that provides access to outside networks including the Internet for allowing streaming applications and other over-the-top communications. Other embodiments provide streamed data to the system using a set-top box that delivers the data over the HDMI connection of an input block. Still other embodiments provide streamed data to the device using the RF connection of the input block.

Device 1000 may provide an output signal to various output devices, including a display 1050, speakers 1060, and other peripheral devices not shown. The other peripheral devices may include, in various examples of embodiments, one or more of a stand-alone DVR, a disk player, a stereo system, a lighting system, and other devices that provide a function based on the output of the device 1000. In various embodiments, control signals are communicated between the device 1000 and the display 1050, speakers 1060, or other peripheral devices, using signaling such as AV.Link, CEC, or other communications protocols that enable device-to-device control with or without user intervention. The output devices may be communicatively coupled to device 1000 via dedicated connections through respective interfaces 1010, and 1020. Alternatively, the output devices may be connected to device using the communications channel via the communications interface. The display 1050 and speakers 1060 may be integrated in a single unit with the other components of in an electronic device, for example, a television, a tablet or a mobile telephone device. The display 1050 and speaker 1060 may alternatively be separate from one or more of the other components, for example, if the circuit 100 is part of a separate set-top box. In various embodiments in which the display 1050 and speakers 1060 are external components, the output signal may be provided via dedicated output connections, including, for example, HDMI ports, USB ports, or COMP outputs.

Reference to “one embodiment” or “an embodiment” or “one implementation” or “an implementation”, as well as other variations thereof, means that a particular feature, structure, characteristic, and so forth described in connection with the embodiment is included in at least one embodiment. Thus, the appearances of the phrase “in one embodiment” or “in an embodiment” or “in one implementation” or “in an implementation”, as well any other variations, appearing in various places throughout this application are not necessarily all referring to the same embodiment.

1. A circuit, comprising:
a multi-input logic gate coupled to a power amplifier for wireless transmission
wherein a first input of the logic gate is coupled to a first wireless transceiver; and
a second input of the gate is coupled to one or more wireless devices.

2. The circuit according to claim 1, wherein the first wireless transceiver is a wifi device.

3. The circuit according to claim 2, wherein the one or more wireless devices operate in the same wireless band as the wifi device.

4. The circuit according to claim 1, wherein an output of the multi-input logic gate is coupled to an enable input of the power amplifier.

5. The circuit according to claim 1, wherein the multi-input logic gate is an AND gate.

6. The circuit according to claim 1, wherein an output of the wireless devices are coupled via an OR gate to a control line coupled to the first input of the logic gate.

7. The circuit according to claim 1, wherein an input of the power amplifier is coupled to a controllable switch for disconnecting the input.

8. The circuit according to claim 7, wherein the controllable switch terminates the input signal via a resistance load.

9. circuit comprising a controllable switch coupled to a power amplifier for wireless transmission wherein the switch is controllable by a wireless transceiver to terminate an input signal to the power amplifier.

10. An electronic device comprising the circuit according to claim 1.

11. The electronic device according to claim 10, comprising a gateway.

12. The electronic device according to claim 10, comprising a tablet device.

13. The electronic device according to claim 10, comprising a smart phone.
